(19) United States
(12) Patent Application Publication
(10) Pub. No.: US 2025/0159946 A1
(43) Pub. Date: May 15, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Kyung-Eun BYUN, Suwon-si (KR); Baekwon PARK, Suwon-si (KR); Keunwook SHIN, Suwon-si (KR); Changhyun KIM, Suwon-si (KR); Minsu SEOL, Suwon-si (KR); Joungeun YOO, Suwon-si (KR); Hyunmi LEE, Suwon-si (KR)

(73) Assignee: Samsung Electronics Co., Ltd., Suwon-si (KR)

(21) Appl. No.: 18/811,194

(22) Filed: Aug. 21, 2024

(30) Foreign Application Priority Data
Nov. 10, 2023 (KR) 10-2023-0155603

(51) Int. Cl. H01L 29/76; H01L 21/02; H01L 21/443; H01L 29/06; H01L 29/24; H01L 29/423; H01L 29/49; H01L 29/66; H01L 29/775; H01L 29/786

(52) U.S. Cl. CPC H10D 48/362; H01L 21/02568; H01L 21/443; H10D 30/43; H10D 30/6735; H10D 30/6739; H10D 30/6757; H10D 62/121; H10D 62/80; H10D 99/00

(57) ABSTRACT

A semiconductor device may include a gate electrode, a metal nitride layer on the gate electrode, a gate insulating film on the metal nitride layer, a channel on the gate insulating film, a source electrode in one side of the channel, and a drain electrode in another side of the channel.

### CROSS-REFERENCE TO RELATED APPLICATION

This application claims the benefit of Korean Patent Application No. 10-2023-0155603, filed on Nov. 10, 2023, in the Korean Intellectual Property Office, the disclosure of which is incorporated herein in its entirety by reference.

### BACKGROUND

### 1. Field

The disclosure relates to semiconductor devices configured to prevent oxidization of a gate electrode and methods of manufacturing the same.

### 2. Description of the Related Art

As miniaturization to improve the integration of semiconductor devices progresses, performance limitations due to scaling of three-dimensional (3D) bulk materials are emerging. To overcome the scaling limitations, researches on the use of two-dimensional layered materials have been conducted. As the 2D layered materials have stable and excellent properties even at a thickness of 1 nm or less, these materials are attracting attention as next-generation materials that can overcome the limitations of performance degradation due to scaling of the existing 3D bulk materials. For example, in the case of a silicon channel, as the channel thickness decreases, mobility decreases and a threshold voltage (Vth) distribution increases, and as the channel length decreases, performance degradation becomes severe due to the short channel effect. In contrast, a two-dimensional semiconductor material channel, even at a thin thickness of 1 nm or less, not only has excellent performance, but also has a short channel effect less than that of the silicon channel.

In the case of a semiconductor device including a silicon channel, it is not possible to first firm a gate electrode and then form a channel later. However, in the case of a two-dimensional semiconductor material that is a deposition type semiconductor, it may be possible to form a channel later after depositing a gate electrode. In this case, when a gate insulating film is deposited on a gate electrode, the gate electrode is oxidized so that the performance of a gate electrode decreases.

### SUMMARY

Some example embodiments of the present disclosure provide semiconductor devices configured to prevent oxidization of a gate electrode.

Some example embodiments of the present disclosure provide methods of manufacturing a semiconductor device that may prevent oxidization of a gate electrode.

Additional aspects will be set forth in part in the description which follows and, in part, will be apparent from the description, or may be learned by practice of the presented example embodiments.

According to an example embodiment of the disclosure, a semiconductor device may include a gate electrode, a metal nitride layer on the gate electrode, a gate insulating film on the metal nitride layer, a channel on the gate insulating film, a source electrode on one side of the channel, and a drain electrode on another side of the channel.

The metal nitride layer may include a transition metal and nitrogen.

The metal nitride layer may include a material represented by M¹N, where M¹ is Mo, W, Nb, V, Ta, Ti, Zr, or Hf.

The metal nitride layer may have a nitrogen content in a range of about 10 at % to about 50 at %.

The metal nitride layer may have a thickness of about 0 nm to about 3 nm.

The channel may include a material represented by M²X₂, where M² is Mo, W, Nb, V, Ta, Ti, Zr, Hf, To, or Re, and X is S, Se, or Te.

The channel may include MoS₂, MoSe₂, MoTe₂, WS₂, WSe₂, WTe₂, ZrS₂, ZrSe₂, HfS₂, HfSe₂, NbSe₂, or ReSe₂.

The metal nitride layer may further include carbon.

The gate electrode may be in direct contact with the metal nitride layer.

The channel may include one to ten layers of two-dimensional semiconductor material layers.

According to an example embodiment of the disclosure, a method of manufacturing a semiconductor device includes depositing a metal layer on a gate electrode, forming a metal nitride layer by reacting nitrogen to the metal layer, forming a gate insulating film on the metal nitride layer, forming a channel on the gate insulating film, and forming a source electrode and a drain electrode on opposite sides of the channel.

### BRIEF DESCRIPTION OF THE DRAWINGS

These and/or other aspects will become apparent and more readily appreciated from the following description of some example embodiments, taken in conjunction with the accompanying drawings in which:

FIG. 1 is a schematic plan view of a semiconductor device according to an example embodiment;

FIG. 2 is a cross-sectional view of the semiconductor device of FIG. 1 taken along line A-A′ of FIG. 1;

FIG. 3 is a cross-sectional view of the semiconductor device of FIG. 1 taken along line B-B′ of FIG. 1;

FIG. 4 is a cross-sectional view of a semiconductor device according to another example embodiment;

FIG. 5 is a cross-sectional view of the semiconductor device of FIG. 4 taken along line C-C′ of FIG. 4;

FIG. 6 is a flowchart showing a method of manufacturing a semiconductor device, according to an example embodiment;

FIG. 7 is a schematic block diagram of a display driving integrated circuit (display driver IC: DDI) including a semiconductor device according to an example embodiment and a display device including the DDI;

FIG. 8 is a circuit diagram of an inverter including a semiconductor device according to an example embodiment;

FIG. 9 is a circuit diagram of an SRAM device including a semiconductor device according to an example embodiment;

FIG. 10 is a circuit diagram of a NAND circuit including a semiconductor device according to an example embodiment;

FIG. 11 is a block diagram of an electronic system including a semiconductor device according to an example embodiment; and

FIG. 12 is a block diagram of an electronic system including a semiconductor device according to an example embodiment.

### DETAILED DESCRIPTION

Reference will now be made in detail to some example embodiments, which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Semiconductor devices and methods of manufacturing the same according to various example embodiments are described in detail with reference to the accompanying drawings. Throughout the drawings, like reference numerals denote like elements, and sizes of components in the drawings may be exaggerated for convenience of explanation and clarity. Terms such as “first” and “second” are used herein merely to describe a variety of constituent elements, but the constituent elements are not limited by the terms. Such terms are used only for the purpose of distinguishing one constituent element from another constituent element.

As used herein, the singular forms “a,” “an,” and “the” are intended to include the plural forms as well, unless the context clearly indicates otherwise. Furthermore, when a part may “include” a certain constituent element, unless specified otherwise, it may not be construed to exclude another constituent element but may be construed to further include other constituent elements. Furthermore, the size or thickness of each constituent element illustrated in the drawings may be exaggerated for clarity of explanation. Furthermore, when a material layer is described to exist on another layer, the material layer may exist directly on the other layer or a third layer may be interposed therebetween. Since a material forming each layer in the following embodiments is exemplary, other materials may be used therefor.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

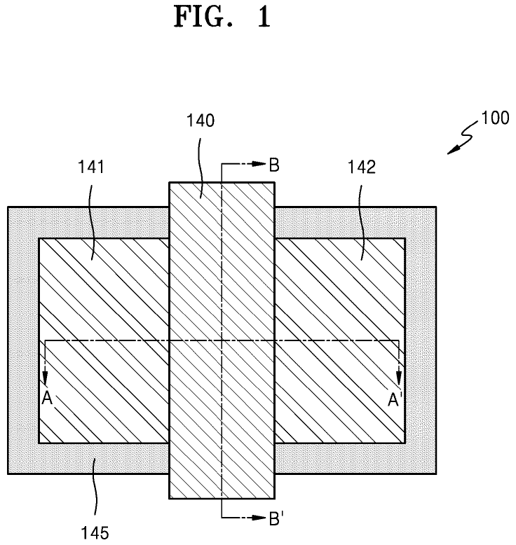

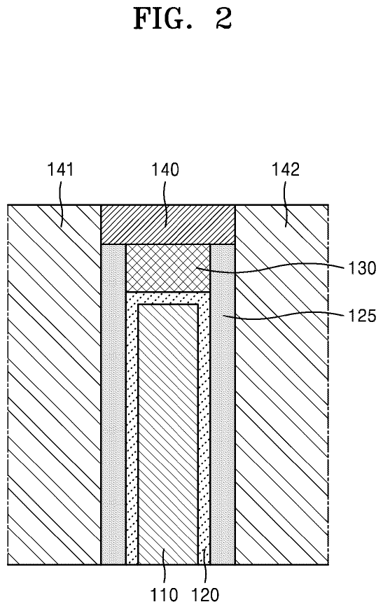

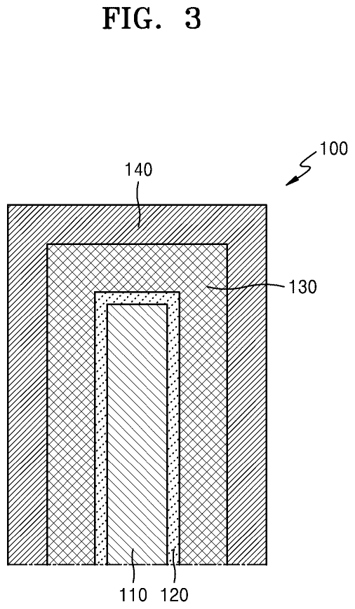

FIG. 1 is a schematic plan view of a semiconductor device 100 according to an example embodiment. FIG. 2 is a cross-sectional view of the semiconductor device 100 of FIG. 1 taken along line A-A′ of FIG. 1. FIG. 3 is a cross-sectional view of the semiconductor device 100 of FIG. 1 taken along line B-B′ of FIG. 1.

The semiconductor device 100 may include a gate electrode 110, a metal nitride layer 120 on the gate electrode 110, a gate insulating film 130 on the metal nitride layer 120, and a channel 140 on the gate insulating film 130.

A source electrode 141 may be arranged in one side of the channel 140, and a drain electrode 142 may be arranged in another side thereof. The source electrode 141 and the drain electrode 142 may not be in direct contact with the channel 140. However, example embodiments of the present disclosure are not limited thereto, and the source electrode 141 and the drain electrode 142 may be connected to the channel 140 via another layer. In any case, the source electrode 141 and the drain electrode 142 may be electrically connected to the channel 140.

An insulator 125 may be further provided between the source electrode 141 and the metal nitride layer 120 and between the drain electrode 142 and the metal nitride layer 120. The insulator 125 may be provided to surround the source electrode 141 and the drain electrode 142.

The gate electrode 110 may include a metal material or a conductive oxide. The metal material may include, for example, Au, Ti, TiN, TaN, W, Mo, WN, Pt, Ni, or a combination thereof. The conductive oxide may include, for example, an indium tin oxide (ITO), an indium zinc oxide (IZO), an indium zinc oxide (IZO), or the like. Alternatively, the gate electrode 110 may include the same material as the source electrode 141 and the drain electrode 142. However, example embodiments of the present disclosure are not limited thereto. A chemical formula used in the specification refers to a material formed of elements included in each chemical formula, and may not a chemical formula representing a stoichiometric relationship.

The metal nitride layer 120 may surround the entire surfaces of the gate electrode 110 except a lower surface thereof. The metal nitride layer 120 may include metal and nitrogen. The metal nitride layer 120 may be represented by, for example, MIN, where M¹ denotes metal and N denotes nitrogen. M¹ may include, for example, transition metal. M¹ may include Mo, W, Nb, V, Ta, Ti, Zr, or Hf. The metal nitride layer 120 may include MON, WN, NbN, VN, TaN, TiN, ZrN, or HfN.

In some example embodiments, the metal nitride layer 120 may further include carbon. In this case, the metal nitride layer 120 may be represented by M¹NC. Alternatively, the metal nitride layer 120 may further include oxygen. In this case, the metal nitride layer 120 may be represented by M¹NO. The metal nitride layer 120 may have a thickness of about 0 nm to about 3 nm. The metal nitride layer 120 may have a thickness of about 0 nm to about 2 nm. The metal nitride layer 120 may have a nitrogen content in a range of about 10 at % to about 50 at %.

As a work function of the metal nitride layer 120 varies depending on a nitrogen composition ratio, the threshold voltage of the semiconductor device 100 may be adjusted. Furthermore, the metal nitride layer 120 may prevent or reduce the gate electrode 110 from being oxidized when the gate insulating film 130 is deposited on the gate electrode 110.

The gate insulating film 130 may be provided between the gate electrode 110 and the channel 140 to cover three side surfaces of the metal nitride layer 120.

The gate insulating film 130 insulates between the gate electrode 110 and the channel 140, and may restrict a leakage current. The gate insulating film 130 may include at least one of a low-doped silicon, SiO₂, Al₂O₃, HfO₂, or Si₃N₄. The gate insulating film 130 may include a high-k dielectric material that is a high dielectric constant material. The gate insulating film 130 may include, for example, a zirconium hafnium oxide, a lanthanum oxide, or the like. However, the gate insulating film 130 is not limited thereto and may include various types of insulating materials.

The channel 140 may include a two-dimensional semiconductor material. The channel 140 may have a thickness of about 0 nm to about 3 nm. The channel 140 may have a thickness of about 0 nm to about 2 nm.

The two-dimensional semiconductor material may refer to a semiconductor material having a two-dimensional crystal structure, and may have a monolayer or multilayer structure. The two-dimensional semiconductor material exhibits superior electrical characteristics, and even when a thickness thereof decreases to a nano scale, the characteristics of the two-dimensional semiconductor material are not changed substantially and high mobility is maintained. Thus, the two-dimensional semiconductor material may be applied to various devices. Each layer forming or constituting the two-dimensional semiconductor material may have a thickness at an atomic level. The channel 140 may include one to ten layers of two-dimensional semiconductor material layers.

The two-dimensional semiconductor material may include, for example, at least one of graphene, black phosphorus, and transition metal dichalcogenide (TMD). The graphene is a material having a hexagonal honeycomb structure, in which carbon atoms are two-dimensionally bonded to each other, and has advantages of high electrical mobility, excellent thermal properties, chemically stability, and a large surface, compared with silicon (Si). Black phosphorus is a material in which black phosphorus atoms are two-dimensionally bonded to each other.

TMD may be represented by, for example, M²X₂, where M² denotes transition metal and X denotes a chalcogen element. For example, M² may include Mo, W, Nb, V, Ta, Ti, Zr, Hf, To, or Re, and X may include S, Se, or Te. Accordingly, for example, TMD may include MoS₂, MoSe₂, MoTe₂, WS₂, WSe₂, WTe₂, ZrS₂, ZrSe₂, HfS₂, HfSe₂, NbSe₂, ReSe₂, or the like.

In some example embodiments, the two-dimensional semiconductor material may include CuS that is a compound of Cu that is transition metal and S that is a chalcogen element. The two-dimensional semiconductor material may be a chalcogenide material including non-transition metal. The non-transition metal may include, for example, Ga, In, Sn, Ge, Pb, or the like. In this case, the two-dimensional semiconductor material may include a compound of non-transition metal, such as Ga, In, Sn, Ge, Pb, or the like, and a chalcogen element, such as S, Se, or Te. For example, the two-dimensional semiconductor material may include SnSe₂, GaS, GaSe, GaTe, GeSe, In₂Se₃, InSnS₂, and the like. However, the materials described above are just examples, and other materials may be used as the two-dimensional semiconductor material.

The two-dimensional semiconductor material may be doped with a p-type dopant or an n-type dopant to adjust mobility. A p-type dopant and an n-type dopant used for, for example, graphene, carbon nanotube (CNT), or the like, may be used as the p-type dopant and the n-type dopant. The p-type dopant or the n-type dopant may be doped in a method, such as ion implantation or chemical doping.

A source of a p-type dopant may include, for example, ionic liquids such as NO₂BF₄, NOBF₄, NO₂SbF₆, or the like, acidic compounds such as HCl, H₂PO₄, CH₃COOH, H₂SO₄, HNO₃, or the like; and organic compounds, such as dichloro dicyano quinone (DDQ), oxone, dimyristoyl phosphatidylinositol (DMPI), trifluoromethanesulfoneimide, or the like. In some example embodiments, a source of a p-type dopant may include HPtCl₄, AuCl₃, HAuCl₄, silver trifluoromethanesulfonate (AgOTf), AgNO₃, H₂PdCl₆, Pd(OAc)₂, Cu(CN)₂, or the like.

A source of an n-type dopant may include, for example, a reduction product of a substituted or unsubstituted nicotinamide, a reduction product of a compound which is chemically bound to a substituted or unsubstituted nicotinamide, and a compound comprising at least two pyridinium moieties in which a nitrogen atom of at least one of the pyridinium moieties is reduced. For example, the source of an n-type dopant may include nicotinamide mononucleotide-H (NMNH), nicotinamide adenine dinucleotide-H (NADH), nicotinamide adenine dinucleotide phosphate-H (NADPH), or viologen. In some example embodiments, the source of an n-type dopant may include a polymer such as polyethylenimine (PEI) or the like. In some example embodiments, the n-type dopant may include alkali metal such as K, Li, or the like. The p-type dopant ad the n-type dopant material described above are examples, and various other materials may be used as the dopants.

The channel 140 may have a monolayer or multilayer structure, and each layer may have a thickness at an atomic level. The channel 140 may include, for example, one layer to ten layers. For example, the channel 140 may include one layer to five layers. However, example embodiments of the present disclosure are not limited thereto.

The source electrode 141 and the drain electrode 142 may include a metal material having electrical conductivity. For example, the source electrode 141 and the drain electrode 142 may each include magnesium (Mg), aluminum (AI), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), or a combination thereof. An insulating layer 145 may further be provided around the source electrode 141 and the drain electrode 142.

The source electrode 141 and the drain electrode 142 are electrically connected to the channel 140 and are insulated by the insulator 125 from the gate electrode 110.

The source electrode 141 and the drain electrode 142 may have a thickness from a lower surface of the gate electrode 110 to an upper surface of the channel 140.

Referring to FIG. 3, the metal nitride layer 120 may be provided to surround the gate electrode 110, and the gate insulating film 130 may be provided to surround the metal nitride layer 120. The channel 140 may be provided to surround the gate insulating film 130.

In the semiconductor device 100, the channel 140 may be provided to face three surfaces of the gate electrode 110. As a facing area between the gate electrode 110 and the channel 140 increases, a short channel effect may decrease, which reduces a leakage current so that the performance of the semiconductor device 100 may increase.

In the semiconductor device 100, the metal nitride layer 120 is provided on the gate electrode 110, and the gate insulating film 130 is provided on the metal nitride layer 120, thereby reducing or preventing the oxidization of the gate electrode 110. The semiconductor device 100 may be employed in a so-called Fin field effect transistor (FET).

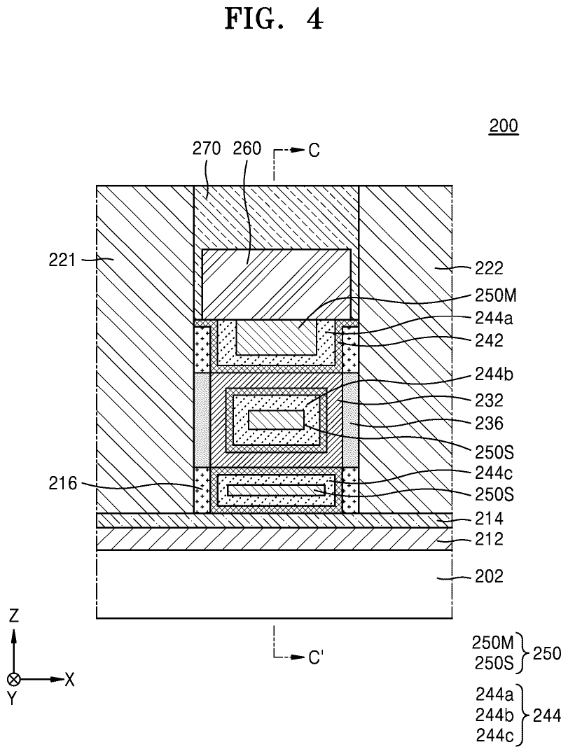

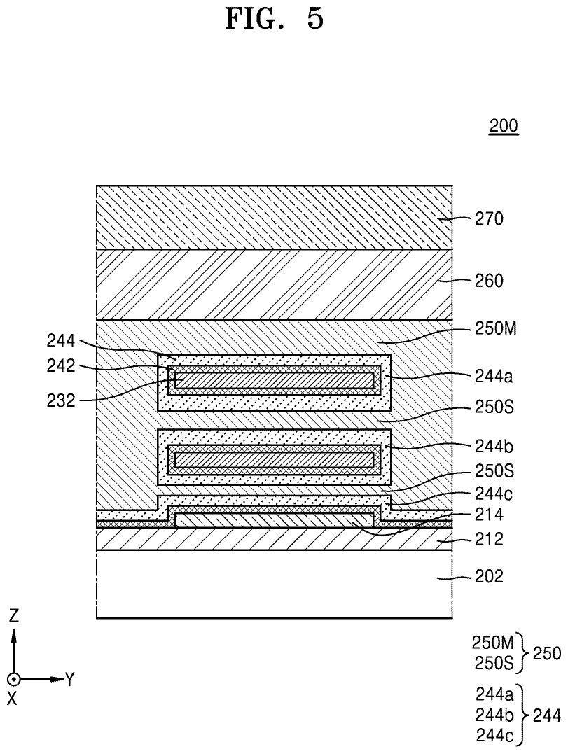

FIG. 4 is a cross-sectional view of a semiconductor device 200 according to another example embodiment, and FIG. 5 is a cross-sectional view of the semiconductor device 200 of FIG. 4 taken along line C-C′ of FIG. 4.

The semiconductor device 200 may include a substrate 202, a channel 232 spaced apart from the substrate 202, a gate insulating film 242 on the channel 232, a metal nitride layer 244 on the gate insulating film 242, and a gate electrode 250 on the metal nitride layer 244. In FIG. 4 the channel 232 has a cross-section of a rectangular ring shape. The channel 232 may have a closed loop cross-section. The gate insulating film 242 may be provided on each of an inner surface and an outer surface of the channel 232. The gate insulating film 242 may be provided to directly contact the channel 232.

The gate electrode 250 may include a main gate portion 250M and a plurality of sub-gate portions 250S. The main gate portion 250M may be arranged above the channel 232 and may extend in a second horizontal direction (Y direction). The sub-gate portions 250S may be integrally connected to the main gate portion 250M. In a vertical direction (Z direction), the thickness of each of the sub-gate portions 250S may be less than that of the main gate portion 250M. In the vertical direction (Z direction), the thicknesses of the main gate portion 250M, the upper sub-gate portions 250S, and the lower sub-gate portions 250S may decrease in order.

The gate electrode 250 may individually include metal, metal carbide, or a combination thereof. The metal may include at least one of Ti, W, Ru, Nb, Mo, Hf, Ni, Co, Pt, Yb, Tb, Dy, Er, or Pd. The metal carbide may include TiAlC. However, the material forming the gate electrode 250 is not limited thereto. The gate electrode 250 may be provided to surround four surfaces of the channel 232. Thus, even when a channel length decreases because a facing area between the gate electrode 250 and the channel 232 increases, the short channel effect may be reduced.

The metal nitride layer 244 may include a first metal nitride layer 244a, a second metal nitride layer 244b, and a third metal nitride layer 244c. The first metal nitride layer 244a, the second metal nitride layer 244b, and the third metal nitride layer 244c may be integrally connected to one another. The first metal nitride layer 244a may be arranged above the channel 232, the second metal nitride layer 244b may be arranged inside the channel 232, and the third metal nitride layer 244c may be arranged below the channel 232.

The gate insulating film 242 may be provided between the gate electrode 250 and the channel 232. The gate insulating film 242 may have a thickness less than that of the metal nitride layer 244. The thickness may represent a thickness along a center axis of the semiconductor device 200. In an example embodiment, the gate insulating film 242 may have a stack structure of an interface insulating film and a high-k insulating film. The interface insulating film may include a low dielectric material film with a dielectric constant of about 9 or less, for example, a silicon oxide film, a silicon oxynitride film, or a combination thereof. In some example embodiments, the interface insulating film may be omitted. The high-k insulating film may include a material with a dielectric constant greater than that of a silicon oxide film. For example, the high-k insulating film may have a dielectric constant of about 10 to about 25. The high-k insulating film may include a hafnium oxide, but example embodiments of the present disclosure are not limited thereto.

An insulating spacer 216 may be arranged on both side walls of the main gate portion 250M and both side walls of the upper sub-gate portion 250S located in a relatively lower end, of the sub-gate portions 250S. The insulating spacer 216 may be apart from the gate electrode 250 with the gate insulating film 242 and the metal nitride layer 244 therebetween. The insulating spacer 216 may include, for example, a silicon nitride, a silicon oxide, SiCN, SiBN, SiON, SiOCN, SiBCN, SiOC, or a combination thereof.

A pair of vertical semiconductor layers 236 may be arranged in the opposite sides of the channel 232. The vertical semiconductor layers 236 may each extend relatively longer in a vertical direction (Z direction) than in a first horizontal direction (X direction), on a plane (e.g., an X-Z plane), which is perpendicular to a second horizontal direction (Y direction). The vertical semiconductor layers 236 may each function as a source/drain region. The vertical semiconductor layers 236 may each be in contact with both side surfaces of the channel 232. In some example embodiments, the vertical semiconductor layers 236 may each have a vertical direction length of about 5 nm to about 20 nm in the vertical direction (Z direction). In some example embodiments, the vertical semiconductor layers 236 may each include a two-dimensional semiconductor material doped with impurities, metal, or a multilayered two-dimensional semiconductor material. The two-dimensional semiconductor material may include, for example, transition metal dichalcogenide, and the impurities may include p-type impurities or n-type impurities. The p-type impurities may include, for example, boron, and the n-type impurities may include, for example, phosphorus. In some example embodiments, the concentration of the impurities of the vertical semiconductor layers 236 may be about 10¹⁸/cm³ to about 10²¹/cm³. In some example embodiments, the vertical semiconductor layers 236 may include substantially the same material as that of the channel 232. For example, the channel 232 may include MoS₂, and the vertical semiconductor layers 236 may include MoS₂ doped with impurities. In some example embodiments, the vertical semiconductor layers 236 may be arranged between the insulating spacers 216 in the vertical direction (Z direction). The vertical semiconductor layers 236 may reduce a contact resistance between the channel 232 and source/drain electrodes 221 and 222.

A barrier film 260 and an upper insulating film 270 may be arranged above the main gate portion 250M. The barrier film 260 may cover the upper surface of the main gate portion 250M, and the upper insulating film 270 may cover the upper surface of the barrier film 260. In some example embodiments, the barrier film 260 may include a metal nitride film. For example, the metal nitride film may include TIN. In some example embodiments, the upper insulating film 270 may include a silicon nitride film, a silicon oxide film, or a combination thereof.

The upper insulating film 270 may be arranged to cover both side walls of the barrier film 260. The source electrode 221 and the drain electrode 222 may be arranged in the opposite sides of the channel 232 and the gate electrode 250. The source electrode 221 and the drain electrode 222 may be in contact with the vertical semiconductor layers 236.

A lower insulating film 214 may be provided between the substrate 202 and the gate insulating film 242. The lower insulating film 214 may include, for example, a silicon oxide film, a silicon nitride film, or a combination thereof.

An etch stop layer 212 may be provided between the lower insulating film 214 and the substrate 202. The etch stop layer 212 may include, for example, a silicon oxide film, a silicon nitride film, or a combination thereof.

The semiconductor device 200 may include the vertical semiconductor layers 236 that are in contact with the channel 232 and are also in contact with the source electrode 221 and the drain electrode 222. In this state, as the vertical semiconductor layers 236 are in contact with the source electrode 221 and the drain electrode 222 in side walls with a relatively large area, the resistances of the source electrode 221 and the drain electrode 222 may be reduced. Accordingly, the electrical performance of the semiconductor device 200 may be improved.

In the semiconductor device 200, the metal nitride layer 244 is arranged around the gate electrode 250, and the gate insulating film 242 is arranged on the metal nitride layer 244, and thus, the oxidization of the gate electrode 250 that may occur when the gate insulating film 242 is deposited after the gate electrode 250 is first deposited may be restricted. Furthermore, by adjusting the nitrogen content of the metal nitride layer 244, the threshold voltage of a semiconductor device may be adjusted.

The semiconductor device 200 may include, for example, a gate-all-around field effect transistor (GAAFET) or a multi-bridge-channel field effect transistor (MBCFET). The semiconductor device 200 may form a logic circuit or memory device.

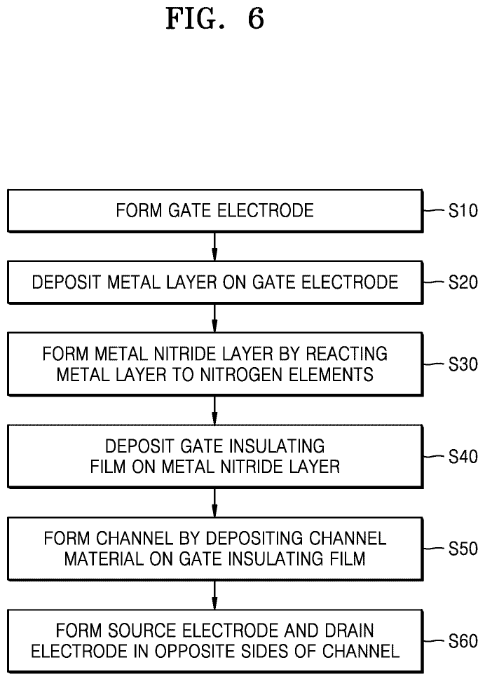

Next, a method of manufacturing a semiconductor device, according to an example embodiment, is described with reference to FIG. 6.

Referring to FIG. 6, a gate electrode is formed (S10), and a metal layer is deposited on the gate electrode (S20). The metal layer may include Mo, W, Nb, V, Ta, Ti, Zr, or Hf. By reacting the metal layer to nitrogen elements, a metal nitride layer may be formed (S30). The metal layer may be formed by a chemical vapor deposition (CVD) process, a physical vapor deposition (PVD) process, an atomic layer deposition (ALD) process, or a combination thereof. The metal nitride layer may include MON, WN, NbN, VN, TaN, TiN, ZrN, or HfN.

A gate insulating film may be deposited on the metal nitride layer (S40). When the gate insulating film is deposited on the metal nitride layer, the oxidization of the gate electrode may be restricted by the metal nitride layer. A channel may be formed by depositing a channel material on the gate insulating film (S50). The gate insulating film and the channel may be formed by a chemical vapor deposition (CVD) process, a physical vapor deposition (PVD) process, an atomic layer deposition (ALD) process, or a combination thereof. A source electrode and a drain electrode may be formed on the opposite sides of the channel (S60). The method of manufacturing a semiconductor device, according to an example embodiment, may be applied to a gate first structure in which, after a gate electrode is first formed, a gate insulating film and a channel are formed.

A semiconductor device according to an example embodiment may include a multi-bridge type nano channel sheet, thereby reducing the short channel effect and effectively reducing the thickness and length of a channel. Furthermore, the semiconductor device according to an example embodiment has an ultra-small size and exhibits superior electrical performance so as to be suitable for application to a highly integrated circuit device.

The semiconductor device according to an example embodiment may form a digital circuit or an analog circuit. In some example embodiments, the semiconductor device may be used as a high voltage transistor or a low voltage transistor. For example, the semiconductor device according to an example embodiment may form a high voltage transistor forming a peripheral circuit of a flash memory device or an electrically erasable and programmable read only memory (EEPROM) device, which is a non-volatile memory device that operates at a high voltage. In some example embodiments, the semiconductor device may be a transistor included in an integrated (IC) chip for a liquid crystal display (LCD) that uses an operating voltage of 10 V or more (e.g., about 20 V to about 30 V), or a transistor included in an IC chip used for a plasma display panel (PDP) that uses an operating voltage of 100 V, or the like.

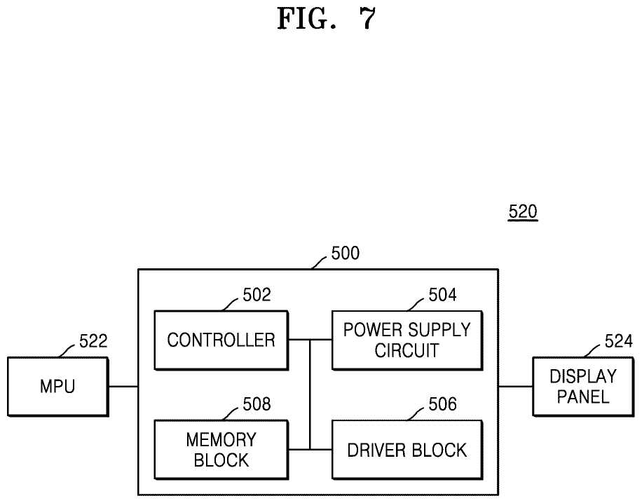

FIG. 7 is a schematic block diagram of a display driving integrated circuit (display driver IC: DDI) 500 including a semiconductor device according to an example embodiment, and a display device 520 including the DDI 500.

Referring to FIG. 7, the DDI 500 may include a controller 502, a power supply circuit 504, a driver block 506, and a memory block 508. The controller 502 receives and decodes a command applied from a main processing device (MPU) 522, and controls the respective blocks of the DDI 500 to implement an operation according to the command. The power supply circuit 504 generates a driving voltage in response to the controller 502. The driver block 506 drives a display panel 524 in response to the control of the controller 502 by using the driving voltage generated by the power supply circuit 504. The display panel 524 may include a liquid crystal display panel or a plasma display panel. The memory block 508 may temporarily store the command input to the controller 502 or control signals output form the controller 502, or as a block for storing necessary data, may include a memory, such as RAM, ROM, and the like. The power supply circuit 504 and the driver block 506 may include the semiconductor device according to one of the example embodiments described above with reference to FIGS. 1 to 5.

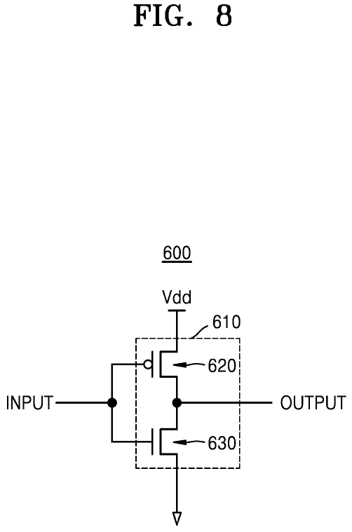

FIG. 8 is a circuit diagram of an inverter 600 according to an example embodiment.

The inverter 600 may include a complementary metal-oxide semiconductor (CMOS) transistor 610. The CMOS transistor 610 may include a p-channel metal-oxide semiconductor (PMOS) transistor 620 and an n-channel metal-oxide semiconductor (NMOS) transistor 630 that are connected in series between a power terminal Vdd and a ground terminal. The CMOS transistor 610 may include the semiconductor device according to one of the example embodiments described above with reference to FIGS. 1 to 5.

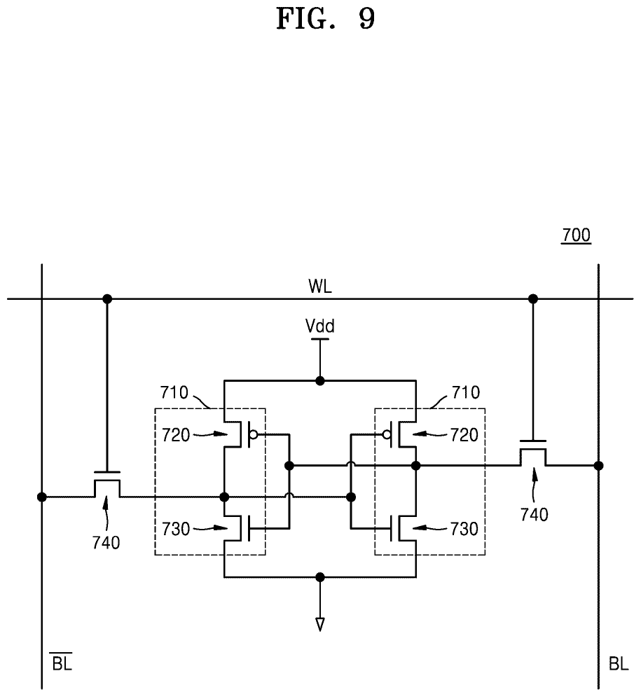

FIG. 9 is a circuit diagram of an SRAM device 700 according to an example embodiment.

The SRAM device 700 may include a pair of driving transistors 710. Each of the driving transistors 710 may include a PMOS transistor 720 and an NMOS transistor 730 that are connected between the power terminal Vdd and the ground terminal. The SRAM device 700 may further include a pair of transmission transistors 740. A source of the transmission transistors 740 is cross-connected to a common node of the PMOS transistor 720 and the NMOS transistor 730 forming the driving transistors 710. The power terminal Vdd is connected to the source of the PMOS transistor 720, and the ground terminal is connected to the source of the NMOS transistor 730. A word line WL may be connected to the gates of the transmission transistors 740, and a bit line BL and an inverted bit line may be connected to the drain of each of the transmission transistors 740.

At least one of the driving transistors 710 and the transmission transistors 740 of the SRAM device 700 may include the semiconductor device according to one of the above example embodiments described above with reference to FIGS. 1 to 5.

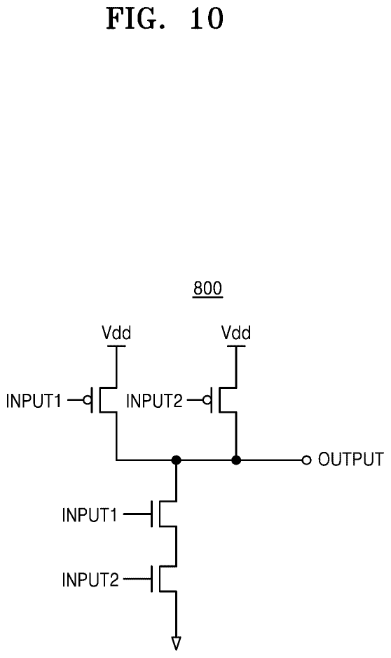

FIG. 10 is a circuit diagram of a CMOS NAND circuit 800 according to an example embodiment.

The CMOS NAND circuit 800 may include a pair of CMOS transistors for transmitting different input signals. The CMOS NAND circuit 800 may include the semiconductor device according to one of the above example embodiments described above with reference to FIGS. 1 to 5.

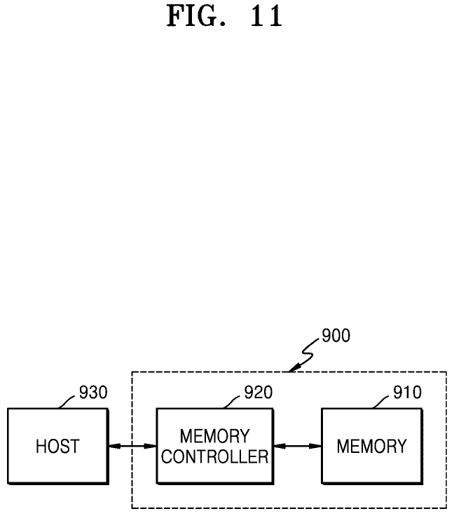

FIG. 11 is a block diagram of an electronic system 900 according to an example embodiment.

The electronic system 900 may include a memory 910 and a memory controller 920. The memory controller 920 may control the memory 910, in response to a request of a host 930, for data read from the memory 910 and/or data write to the memory 910. At least one of the memory 910 and the memory controller 920 may include the semiconductor device according to one of the above example embodiments described above with reference to FIGS. 1 to 5.

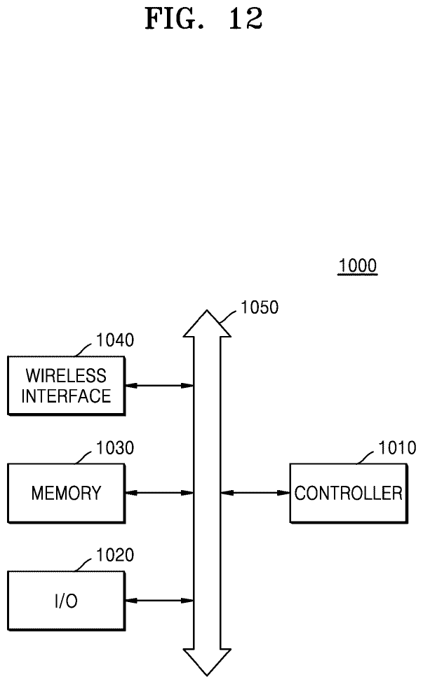

FIG. 12 is a block diagram of an electronic system 1000 according to an example embodiment.

The electronic system 1000 may form a wireless communication apparatus or an apparatus capable of transmitting and/or receiving information in a wireless environment. The electronic system 1000 may include a controller 1010, an input/output device (I/O) 1020, a memory 1030, and a wireless interface 1040, which are connected to one another via a bus 1050.

The controller 1010 may include at least one of a microprocessor, a digital signal processor, or any similar processing device. The input/output device 1020 may include at least one of a keypad, a keyboard, or a display. The memory 1030 may be used to store commands executed by the controller 1010. For example, the memory 1030 may be used to store user data. The electronic system 1000 may use the wireless interface 1040 to transmit/receive through a wireless communication network. The wireless interface 1040 may include an antenna and/or a wireless transceiver. In some example embodiments, the electronic system 1000 may be used for a communication interface protocol of the third-generation communication system, for example, code division multiple access (CDMA), global system for mobile communications (GSM), north American digital cellular (NADC), extended-time division multiple access (E-TDMA), and/or wide band code division multiple access (WCDMA). The electronic system 1000 may include the semiconductor device according to one of the example embodiments described above with reference to FIGS. 1 to 5.

The semiconductor devices according to the above example embodiments may exhibit good electrical performance with an ultra-small structure so as to be applied to integrated circuit devices and achieve miniaturization, and may implement miniaturization, low power, and/or high performance.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that the semiconductor devices and the manufacturing methods thereof described herein should be considered in a descriptive sense only and not for purposes of limitation. Descriptions of features or aspects within one of the example embodiments should typically be considered as available for other similar features or aspects in other example embodiments.

While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a gate electrode;
a metal nitride layer on the gate electrode:
a gate insulating film on the metal nitride layer;
a channel on the gate insulating film;
a source electrode on one side of the channel; and
a drain electrode on another side of the channel.

2. The semiconductor device of claim 1, wherein the metal nitride layer comprises transition metal and nitrogen.

3. The semiconductor device of claim 2, wherein the metal nitride layer comprises a material represented by MIN, where M¹ is Mo, W, Nb, V, Ta, Ti, Zr, or Hf.

4. The semiconductor device of claim 1, wherein the metal nitride layer has a nitrogen content in a range of about 10 at % to about 50 at %.

5. The semiconductor device of claim 1, wherein the metal nitride layer has a thickness of about 0 nm to about 3 nm.

6. The semiconductor device of claim 1, wherein the channel comprises a material represented by M²X₂, where M² is Mo, W, Nb, V, Ta, Ti, Zr, Hf, Tc, or Re, and X is S, Se, or Te.

7. The semiconductor device of claim 1, wherein the channel comprises MoS₂, MoSe₂, MoTe₂, WS₂, WSe₂, WTe₂, ZrS₂, ZrSe₂, HfS₂, HfSe₂, NbSe₂, or ReSe₂.

8. The semiconductor device of claim 1, wherein the metal nitride layer further comprises carbon.

9. The semiconductor device of claim 1, wherein the gate electrode is in direct contact with the metal nitride layer.

10. The semiconductor device of claim 1, wherein the channel comprises one to ten layers of two-dimensional semiconductor material layers.

11. A method of manufacturing a semiconductor device, the method comprising:
depositing a metal layer on a gate electrode;
forming a metal nitride layer by reacting nitrogen to the metal layer;
forming a gate insulating film on the metal nitride layer;
forming a channel on the gate insulating film; and
forming a source electrode and a drain electrode on opposite sides of the channel.

12. The method of claim 11, wherein the metal nitride layer comprises transition metal and nitrogen.

13. The method of claim 12, wherein the metal nitride layer comprises a material represented by M¹N, where M¹ is Mo, W, Nb, V, Ta, Ti, Zr, or Hf.

14. The method of claim 11, wherein the metal nitride layer has a nitrogen content in a range of about 10 at % to about 50 at %.

15. The method of claim 11, wherein the metal nitride layer has a thickness of about 0 nm to about 3 nm.

16. The method of claim 11, wherein the channel comprises a material represented by M²X₂, where M² is Mo, W, Nb, V, Ta, Ti, Zr, Hf, Tc, or Re, and X is S, Se, or Te.

17. The method of claim 11, wherein the channel comprises MoS₂, MoSe₂, MoTe₂, WS₂, WSe₂, WTe₂, ZrS₂, ZrSe₂, HfS₂, HfSe₂, NbSe₂, or ReSe₂.

18. The method of claim 11, wherein the metal nitride layer further comprises carbon.

19. The method of claim 11, wherein the gate electrode is in direct contact with the metal nitride layer.

20. The method of claim 11, wherein the channel comprises one to ten layers of two-dimensional semiconductor material layers.
